(19) United States
(12) Patent Application Publication
(10) Pub. No.: US 2025/0155378 A1
(43) Pub. Date: May 15, 2025

(54) COMPUTER IMPLEMENTED METHOD FOR DEFECT DETECTION IN AN IMAGING DATASET OF AN OBJECT COMPRISING INTEGRATED CIRCUIT PATTERNS USING MACHINE LEARNING MODELS WITH ATTENTION MECHANISM

(71) Applicant: Carl Zeiss SMT GmbH, Oberkochen (DE)

(72) Inventors: Alexander Freytag, Erfurt (DE); Bjoern Froehlich, Jena (DE); Bjoern Barz, Jena (DE); Bjoern Brauer, Magstadt (DE)

(21) Appl. No.: 18/938,425

(22) Filed: Nov. 6, 2024

(30) Foreign Application Priority Data
Nov. 10, 2023 (DE) 102023131368.1

(51) Int. Cl. G01N 21/88; G01N 21/95; G06T 7/00; H01L 21/66

(52) U.S. Cl. CPC G01N 21/8851; G01N 21/9501; G06T 7/001; H01L 22/12; G01N 2021/8887; G06T 2207/20081; G06T 2207/30148

(57) ABSTRACT

The invention relates to a computer implemented method for defect detection comprising: obtaining an imaging dataset and a reference dataset of an object comprising integrated circuit patterns; and detecting defects in the imaging dataset using the imaging dataset and the reference dataset, wherein a machine learning model for defect highlighting is applied to the imaging dataset as input and generates a highlighted defect dataset as output, and wherein the machine learning model for defect highlighting comprises at least one attention mechanism. The invention also relates to computer programs, computer-readable media and corresponding systems.

### CROSS-REFERENCE TO RELATED APPLICATION

This application claims benefit under 35 U.S.C. § 119 (a) of German patent application 10 2023 131368.1, filed on Nov. 10, 2023, which is incorporated herein by reference in its entirety.

### TECHNICAL FIELD

The invention relates to systems and methods for quality assurance of objects comprising integrated circuit patterns, more specifically to a computer implemented method, a computer-readable medium, a computer program product and a corresponding system for defect detection in an imaging dataset of such an object. Using a machine learning model with attention mechanism, defects can be detected reliably and quickly. The method, computer-readable medium, computer program product and system can be utilized for quantitative metrology, process monitoring, defect detection and defect review in objects comprising integrated circuit patterns, e.g., in photolithography masks, reticles or wafers.

### BACKGROUND

Semiconductor manufacturing involves precise manipulation, e.g., etching, of materials such as silicon or oxide at very fine scales in the range of nanometers. Therefore, a quality management process comprising quality assurance and quality control is important for ensuring high quality standards of the manufactured wafers. Quality assurance refers to a set of activities for ensuring high-quality products by preventing any defects that may occur in the development process. Quality control refers to a system of inspecting the final quality of the product. Quality control is part of the quality assurance process.

A wafer made of a thin slice of silicon serves as the substrate for microelectronic devices containing semiconductor structures built in and upon the wafer. The semiconductor structures are constructed layer by layer using repeated processing steps that involve repeated chemical, mechanical, thermal and optical processes. Dimensions, shapes and placements of the semiconductor structures and patterns are subject to several influences. One of the most crucial steps is the photolithography process.

Photolithography is a process used to produce patterns on the substrate. The patterns to be printed on the surface of the substrate are generated by computer-aided-design (CAD). From the design, for each layer a photolithography mask is generated, which contains a magnified image of the computer-generated pattern to be etched into the substrate. The photolithography mask can be further adapted, e.g., by use of optical proximity correction techniques. During the printing process an illuminated image projected from the photolithography mask is focused onto a photoresist thin film formed on the substrate. A semiconductor chip powering mobile phones or tablets comprises, for example, approximately between 80 and 120 patterned layers.

Due to the growing integration density in the semiconductor industry, photolithography masks have to image increasingly smaller structures onto wafers. The aspect ratio and the number of layers of integrated circuits constantly increases and the structures are growing into 3^{rd} (vertical) dimension. The current height of the memory stacks is exceeding a dozen of microns. In contrast, the feature size is becoming smaller. The minimum feature size or critical dimension is below 20 nm, for example 10 nm, 7 nm or 5 nm, and is approaching feature sizes below 3 nm in near future. While the complexity and dimensions of the semiconductor structures are growing into the 3^{rd} dimension, the lateral dimensions of integrated semiconductor structures are becoming smaller. Producing the small structure dimensions imaged onto the wafer requires photolithographic masks or templates for nanoimprint photolithography with ever smaller structures or pattern elements. The production process of photolithographic masks and templates for nanoimprint photolithography is, therefore, becoming increasingly more complex and, as a result, more time-consuming and ultimately also more expensive. With the advent of EUV photolithography scanners, the nature of masks changed from transmission-based to reflection-based patterning.

On account of the tiny structure sizes of the pattern elements of photolithographic masks or templates, it is not possible to exclude errors during mask or template production. The resulting defects can, for example, arise from degeneration of photolithography masks or particle contamination. Of the various defects occurring during semiconductor structure manufacturing, photolithography related defects make up nearly half of the number of defects. Hence, in semiconductor process control, photolithography mask inspection, review, and metrology play a crucial role to monitor systematic defects. Defects detected during quality assurance processes can be used for root cause analysis, for example, to modify or repair the photolithography mask. The defects can also serve as feedback to improve the process parameters of the manufacturing process, e.g., exposure time, focus variation, etc.

Each defect in the photolithography mask can lead to unwanted behavior of the produced wafer, or a wafer can be significantly damaged. Therefore, each defect must be found and repaired if possible and necessary. Reliable and fast defect detection methods are, therefore, important for photolithography masks.

Apart from defect detection in photolithography masks, defect detection in wafers is also crucial for quality management. During the manufacturing of wafers many defects apart from photolithography mask defects can occur, e.g., during etching or deposition. For example, bridge defects can indicate insufficient etching, line breaks can indicate excessive etching, consistently occurring defects can indicate a defective mask and missing structures hint at non-ideal material deposition etc. Therefore, a quality assurance process and a quality control process are important for ensuring high quality standards of the manufactured wafers.

Apart from quality assurance and quality control, defect detection in wafers is also important during process window qualification (PWQ). This process serves for defining windows for a number of process parameters mainly related to different focus and exposure conditions in order to prevent systematic defects. In each iteration, a test wafer is manufactured based on a number of selected process parameters, e.g., exposure time, focus variation, etc., with different dies of the wafer being exposed to different manufacturing conditions. By detecting and analyzing the defects in the different dies based on a quality assurance process, the best manufacturing process parameters can be selected, and a window or range can be established for each process parameter from which the respective process parameter can be selected. In addition, a highly accurate quality control process and device for the metrology of semiconductor structures in wafers is required. The recognized defects can, thus, be used for monitoring the quality of wafers during production or for process window establishment. Reliable and fast defect detection methods are, therefore, important for objects comprising integrated circuit patterns.

In order to analyze large amounts of data requiring large amounts of measurements to be taken, machine learning methods can be used. Machine learning is a field of artificial intelligence. Machine learning methods generally build a parametric machine learning model based on training data consisting of a large number of samples. After training, the method is able to generalize the knowledge gained from the training data to new previously unencountered samples, thereby making predictions for new data. There are many machine learning methods, e.g., linear regression, k-means, support vector machines, decision trees, random forests, clustering methods, or artificial neural networks.

Deep learning is a direction in machine learning describing learning methods that build a hierarchy of learned representations by use of a series of transformations. The most common machine learning model used for deep learning are artificial neural networks with numerous hidden layers between the input layer and the output layer. Due to this complex internal structure, the networks are able to progressively extract higher-level features from raw input data. Each level learns to transform its input data into a more abstract and composite representation, thus deriving low and high level knowledge from the training data. The hidden layers can have differing sizes and tasks such as convolutional or pooling layers.

Existing solutions for detecting defects in imaging datasets of objects comprising integrated circuit patterns such as disclosed in WO2020057644A1 or U.S. Ser. No. 11/507,801 B2 often rely on deep learning algorithms due to the benefits associated with data-driven models. In particular, convolutional neural networks (CNNs) are applied as standard methods for defect detection. However, CNNs have the following shortcomings: they do not take into account global image context due to the limited local context window defined by the convolutional filters. In addition, the strong inductive priors resulting from the convolution operations with fixed (i.e., sample-independent) weights after training limit the learning capacity of the CNNs.

Therefore, it is an aspect of the invention to provide a defect detection method for objects comprising integrated circuit patterns that detects defects with an improved accuracy. It is another aspect of the invention to provide a defect detection method for objects comprising integrated circuit patterns with a reduced computation time. It is another aspect of the invention to provide a defect detection method for objects comprising integrated circuit patterns, which is easily adaptable to different applications or imaging datasets. Another aspect is to reduce the user effort and the required memory space.

The aspects are achieved by the invention specified in the independent claims. Advantageous embodiments and further developments of the invention are specified in the dependent claims.

### SUMMARY

Embodiments of the invention concern computer implemented methods, computer-readable media and systems for defect detection in imaging datasets of objects comprising integrated circuit patterns.

A first embodiment involves a computer implemented method for defect detection comprising: obtaining an imaging dataset and a reference dataset of an object comprising integrated circuit patterns; detecting defects in the imaging dataset using the imaging dataset and the reference dataset, wherein a machine learning model for defect highlighting is applied to the imaging dataset as input and generates a highlighted defect dataset as output, and wherein the machine learning model for defect highlighting comprises at least one attention mechanism.

An integrated circuit pattern can, for example, comprise semiconductor structures. An object comprising integrated circuit patterns can refer, for example, to a photolithography mask, a reticle or a wafer. In a photolithography mask or reticle the integrated circuit patterns can refer to mask structures used to generate semiconductor patterns in a wafer during the photolithography process. In a wafer the integrated circuit patterns can refer to semiconductor structures, which are imprinted on the wafer during the photolithography process.

The object comprising integrated circuit patterns, in particular the photolithography mask, may have an aspect ratio of between 1:1 and 1:4, preferably between 1:1 and 1:2, most preferably of 1:1 or 1:2. The object comprising integrated circuit patterns may have a nearly rectangular shape. The object comprising integrated circuit patterns may be preferably 5 to 7 inches long and wide, most preferably 6 inches long and wide. Alternatively, the object comprising integrated circuit patterns may be 5 to 7 inches long and 10 to 14 inches wide, preferably 6 inches long and 12 inches wide.

The term “defect” refers to a localized deviation of an integrated circuit pattern from an a priori defined norm of the integrated circuit pattern. The norm of the integrated circuit pattern can be defined by a corresponding reference object or dataset, e.g., a model dataset (e.g., using a CAD design) or an acquired predominantly defect-free dataset or a simulated dataset. For instance, a defect of an integrated circuit pattern, e.g., of a semiconductor structure, can result in malfunctioning of an associated semiconductor device. Depending on the detected defect, for example, the photolithography process can be improved, or photolithography masks or wafers can be repaired or discarded.

The imaging dataset can comprise one or more images of one or more portions of the object comprising integrated circuit patterns or of the whole object. According to the techniques described herein, various imaging modalities may be used to acquire the imaging dataset. Imaging datasets can comprise single-channel images or multi-channel images, e.g., focus stacks. For instance, it is possible that the imaging dataset includes 2-D images. It is possible to employ a multi beam scanning electron microscope (mSEM). mSEM employs multiple beams to acquire contemporaneously images in multiple fields of view. For instance, a number of not less than 50 beams could be used or even not less than 90 beams. Each beam covers a separate portion of a surface of the object comprising integrated circuit patterns. Thereby, a large imaging dataset is acquired within a short duration of time. Typically, contemporary machines acquire 4.5 gigapixels per second. For illustration, one square centimeter of a wafer can be imaged with 2 nm pixel size leading to 25 terapixels of data. Other examples for imaging datasets including 2D images relate to imaging modalities such as optical imaging, phase-contrast imaging, x-ray imaging, etc. It is also possible that the imaging dataset is a volumetric 3-D dataset, which can be processed slice-by-slice or as a three-dimensional volume. Here, a crossbeam imaging system including a focused-ion beam (FIB) source, an atomic force microscope (AFM) or a scanning electron microscope (SEM) could be used. Furthermore, magnetic resonance (MR) images, ultrasound images or computed tomography (CT) images could be used. Multimodal imaging datasets may be used, e.g., a combination of x-ray imaging and SEM. The imaging dataset can, additionally or alternatively, comprise aerial images acquired by an aerial imaging system. An aerial image is the radiation intensity distribution at substrate level.

It can be used to simulate the radiation intensity distribution generated by a photolithography mask during the photolithography process. The aerial image measurement system can, for example, be equipped with a staring array sensor or a line-scanning sensor or a time-delayed integration (TDI) sensor.

The reference dataset of the object comprising integrated circuit patterns can be obtained in different ways. It can comprise an acquired imaging dataset using any of the acquisition methods described before for acquiring the imaging dataset, or it can comprise an artificially generated imaging dataset. In an example, the reference dataset is obtained by acquiring images of a reference object comprising integrated circuit patterns. The reference object comprising integrated circuit patterns can, for example, be another instance of the same type of object, or it can be of a different type but comprising at least a portion of the same integrated circuit patterns as the object. The reference dataset can also be obtained from one or more portions of the (same) object comprising integrated circuit patterns, e.g., from another die of the object, for example in case of repetitive structures. The reference dataset can also be obtained using the same die of the same object but acquired at a different time. Alternatively, the reference dataset can be artificially generated. In an example, the reference dataset is obtained from simulated images of the object comprising integrated circuit patterns, e.g., from a model, CAD files, simulated aerial images or by using machine learning models, e.g., for adapting the appearance of a design to the appearance of the imaging dataset to make them comparable. The simulated images can be loaded from a database or a memory or a cloud storage. The reference dataset is preferably predominantly defect-free, comprising none or only few defects (e.g., less than 10%, preferably less than 5% of the reference dataset comprises a defect).

A machine learning model is a parametric model whose parameter values can be obtained from training the model using training data. The estimated parameters are the result of a machine learning method for training the machine learning model. Machine learning models comprise, for example, neural networks, support vector machines, decision trees, etc. Hyperparameters of a machine learning method comprise hyperparameters that define the architecture of the machine learning model, e.g., the number and sizes of layers of a neural network, the number of branches in a decision tree, etc., and hyperparameters that define the training of the machine learning model, e.g., the learning rate. During training, model parameters of the machine learning model are derived from the training data that adapt the machine learning model to the training data. These model parameters include, for example, the weights and biases of neural networks, the hyperplanes of a support vector machine, the decisions within the nodes of a decision tree, etc. A trained machine learning model can be used to make predictions on previously unseen data. The hyperparameter values of a machine learning model can be selected by a user, or they can be automatically optimized using hyperparameter optimization techniques.

By using machine learning models, the computation time for defect detection can be reduced. The machine learning model learns offline during training from sample training data. This process can be time-consuming. However, during inference, a single application or forward-pass through the trained model is sufficient to obtain a prediction for input data. Thus, by using machine learning models, the computation time for defect detection can be reduced.

The machine learning model is used to highlight defects in the imaging dataset, thereby obtaining a highlighted defect dataset. Highlighting a defect means to modify the imaging dataset to improve the visibility of the defect within the imaging dataset. For example, a defect can be highlighted by modifying properties of the defect, e.g., the intensity, color, contrast, sharpness, size, shape, location, etc. The highlighted defect dataset can also comprise a segmentation, or it can comprise defect indicators such as bounding boxes of any size and shape, contours, center points, coordinates, circumcircles, etc. The highlighted defect dataset can comprise a version of the imaging dataset, within which the defects are replaced by some other image content. The highlighted defect dataset can also comprise a defect-free version of the imaging dataset, i.e., the imaging dataset wherein defects are replaced by an approximation of the imaging dataset without defects. Alternatively, properties of the imaging dataset outside the defects can be modified, e.g., the intensity, color, contrast, sharpness, size, shape, location, etc. In this way, the visibility of the defect is improved such that the defect can be detected more easily, e.g., by comparing the highlighted defect dataset to a reference dataset.

The term “attention mechanism” refers to a computational method that is part of a machine learning method that transforms input data to output data. The computational method is used for recognizing relationships between parts of the input data that are relevant for the transformation. To recognize relationships between parts of the input data, the attention mechanism can transform an element of the input data into a new representation, thereby making use of one or more other elements of the input data and their similarity to the element. The transformation can comprise a similarity function and an aggregation function, wherein the similarity function assesses the similarity of an element to one or more other elements in the input data, and the aggregation function maps the element and the one or more other elements and their similarities to the new representation of the element. The aggregation function can generate the new representation of the element using a weighted combination of the one or more other elements in the input data, wherein the weights depend on the similarities of the element to the one or more other elements. An attention mechanism can have at least one trainable parameter, preferably for pre-processing elements of the input data such that the similarity function is applied to the pre-processed elements. The at least one trainable parameter can define at least one projection matrix which is used to pre-process the elements of the input data. Throughout the aforementioned definition of the term “attention mechanism,” instead of elements of the input data, representations of the elements of the input data can be processed.

In contrast to convolutional layers or fully-connected layers, e.g., in CNNs, the weights applied to the elements of the input data depend on the input data, more precisely on the similarity of each element to the other elements of the input data, instead of being fixed after training. Furthermore, in contrast to convolutional operations, the attention mechanism does not require a fixed sequence of the elements in the input data.

Instead, context windows of dynamic or global size can be implemented instead of using context windows of fixed size as in case of convolutions. Finally, in contrast to fully-connected layers, the attention mechanism does not require a fixed number of elements in the input data but can be applied to input data sets of arbitrary size. An attention mechanism can, thus, be understood as a location-dependent convolution with input data dependent weights and a context window of arbitrary size. For example, the context window can comprise the complete input data. In case of an imaging dataset, the input data can, for example, comprise a sequence of patches that forms a partition of the imaging dataset, or a sequence of overlapping patches.

By using at least one attention mechanism in the machine learning model, the structural context of the circuit patterns in the photolithography mask can be taken into account for defect detection, which is particularly important for defect detection in objects comprising integrated circuit patterns. In fact, defects or structural variations in integrated circuit patterns can often be detected only by considering the spatial context of the structures. By using attention mechanisms, this spatial context is not limited to the local receptive field of a convolution but can comprise large contexts or even the complete input data, i.e., the global context. Thus, by using at least one attention mechanism, the accuracy of the predicted defects is improved for objects comprising integrated circuit patterns.

According to an example, the reference dataset is generated using a further machine learning model. For example, the reference dataset can be a simulated dataset, e.g., a design dataset obtained from a CAD file. Then the further machine learning model can be used to adapt the appearance of the reference dataset to the appearance of the imaging dataset to make both datasets comparable. In this way, the accuracy of the detected defects is improved.

In another example, the further machine learning model can be used to modify or mark locations in the reference dataset in order to prevent false positive defect detections in the reference dataset, e.g., by regularizing structures, e.g., patterns of structures, distances or dimensions of structures, or by marking irregular structures that are ignored during defect detection. In this way, false positive defect detections, e.g., due to irregular structures in the reference dataset, are reduced.

According to an aspect, the further machine learning model comprises at least one attention mechanism. Since attention mechanisms can be used to improve the accuracy of defect detection methods by taking into account spatial context of structures in other parts of the reference dataset, the generated reference dataset can be improved in this way.

According to an embodiment of the invention, defects are detected by comparing the highlighted defect dataset to the reference dataset. The comparison can, for example, be carried out by computing a difference image, by using statistical methods, by using a machine learning model that is trained to detect defects from the highlighted imaging dataset and corresponding reference dataset, by using rule-based methods that define rules for defect detection, etc.

According to another embodiment of the invention, the machine learning model for defect highlighting uses the reference dataset as additional input. Thus, the machine learning model directly maps the imaging dataset and the reference dataset to the highlighted defects, e.g., in the form of a segmentation, bounding boxes or other defect indicators. In this way, the machine learning model for defect highlighting is trained to directly derive defects from the imaging dataset and the reference dataset instead of using consecutive steps for defect highlighting and defect detection. Thus, the accuracy of the detected defects can be improved.

According to an aspect, the machine learning model for defect highlighting reconstructs the imaging dataset and the reference dataset, and the highlighted defect dataset is obtained by comparing the reconstruction of the imaging dataset to the reconstruction of the reference dataset. The reconstruction can, for example, be carried out using an autoencoder neural network with attention mechanism. Since they are reconstructed in the same way, the reconstructed imaging dataset and the reconstructed reference dataset are highly similar or identical within regions without defects. Thus, defects can be accurately detected by comparing the imaging dataset to the reference dataset.

In a preferred embodiment of the invention, the machine learning model for defect highlighting computes a reconstruction of the input including the defects. Contrary to autoencoders that rely on the concept of reconstructing only defect-free parts of the imaging dataset, the machine learning model for defect highlighting reconstructs the defects as well. In this way, defects can be detected by comparing the highlighted defect dataset to the reference dataset. Since reference datasets are predominantly defect-free, defects can be detected with increased accuracy, even in difficult cases that cannot be detected by autoencoders.

According to an aspect, the machine learning model for defect highlighting reconstructs defective regions in the input with a higher accuracy than defect-free regions. To this end, the machine learning model can be trained using a loss function that applies a higher penalty to deviations of the reconstruction from the imaging dataset within defective regions than within defect-free regions. By reconstructing the defects with a particularly high accuracy, the defects can be determined in a particularly detailed way with respect to the reference dataset. This is, for example, not the case for autoencoder based defect detection. Autoencoders are usually able to reconstruct a defect at least partially, some of them even almost completely, thereby preventing an accurate detection of some parts of the defect.

In an example, the machine learning model for defect highlighting amplifies the defects in the input. A defect can be amplified by modifying a property of the defect such that the defect with the modified property can be distinguished more easily from non-defective parts of the input. A property that can be used to distinguish the defect from non-defective parts of the input includes contrast, intensity, mean intensity, intensity variation, brightness, edge strength, size, shape, morphology, texture, location, orientation, location or orientation with respect to other structures, etc. By amplifying defects, the detection of defects, in particular of details of the defects, is simplified. Thus, the accuracy of the defect detection is improved.

In an example, the machine learning model for defect highlighting comprises a convolutional neural network that contains at least one attention mechanism. By including at least one attention mechanism into a CNN, the CNN can use information from the larger parts or even the whole input instead of only local information due to the limited receptive fields of the convolutions. Thus, the accuracy of predictions of the CNN and, thus, of the detected defects is improved.

In an example, the convolutional neural network comprising at least one attention mechanism comprises an encoder—decoder architecture. The encoder maps the input to a feature space called bottleneck that is usually of lower dimensional spatial dimension, and the decoder maps the feature vectors in the feature space to the output.

Due to the compression of the input in the feature space, only the most relevant features of the input are preserved, yielding a reconstruction of the input, e.g., with reduced noise or defects. Thus, the accuracy of the prediction of the machine learning model and, thus, the accuracy of the detected defects is improved.

In an example, the convolution neural network is configured as a U-Net. A U-Net contains an encoder—decoder architecture and additional skip connections between layers of the encoder and layers of the decoder. The skip connections are used to directly access information in the encoder before the reduction in the bottleneck. In this way, details of the input can be preserved in the output. Thus, the accuracy of the prediction of the machine learning model and, thus, the accuracy of the detected defects is improved.

In an example, the machine learning model for defect highlighting comprises a Vision Transformer. A Vision Transformer is described in the paper “An Image is Worth 16×16 Words: Transformers for Image Recognition at Scale, Alexey Dosovitskiy, Lucas Beyer, Alexander Kolesnikov, Dirk Weissenborn, Xiaohua Zhai, Thomas Unterthiner, Mostafa Dehghani, Matthias Minderer, Georg Heigold, Sylvain Gelly, Jakob Uszkoreit, Neil Houlsby, Computing Research Repository, 2020.” Another Vision Transformer is described in the paper “Swin Transformer: Hierarchical Vision Transformer using Shifted Windows, Ze Liu, Yutong Lin, Yue Cao, Han Hu, Yixuan Wei, Zheng Zhang, Stephen Lin, Bainin Guo, Computing Research Repository, 2021.” The aforementioned papers illustrate two options for Vision Transformers. A person skilled in the art knows that there are further variants of Vision Transformers that can all be used in the context of this invention.

A Vision Transformer is a Transformer that is targeted at vision tasks and, thus, uses a sequence of patches of the imaging dataset as input. Since Vision Transformers take into account spatial relationships of each two patches in the imaging dataset, information from each part of the imaging dataset can influence the prediction result at any other part of the imaging dataset. In this way, global spatial context in the imaging dataset can be considered comprehensively leading to improved defect detection results. A Transformer is a machine learning model that relies on attention mechanisms to draw global dependencies between the input and the output of the machine learning model. It is described in the paper “Attention is all you need, A. Vaswani, N. Shazeer, N. Parmar, J. Uszkoreit, L. Jones, A. Gomez, L. Kaiser, I. Polosukhin, Advances in Neural Information Processing Systems, vol. 30. 2017.”

According to an aspect, the Vision Transformer is pre-trained using masked autoencoding. Masked auto-encoding refers to a training technique that partitions the imaging dataset into patches, iteratively masks at least one of the patches of the imaging dataset and reconstructs the masked patches. The loss function penalizes deviations of the reconstructed patches from the patches of the imaging dataset. In this way, the Vision Transformer learns to accurately reconstruct missing patches in the imaging dataset from their context.

According to an example, the detection of defects using a Vision Transformer comprises: partitioning the imaging dataset of the object comprising integrated circuit patterns into a set of patches; iteratively masking at least one of the patches of the imaging dataset and applying the Vision Transformer machine learning model to reconstruct the at least one masked patch; and obtaining a highlighted defect dataset in the form of a reconstructed imaging dataset from the at least one reconstructed masked patch. By reconstructing an input patch by use of inpainting, i.e., by using only the surrounding input patches for the reconstruction instead of the input patch itself (as, for example, in autoencoders), the reconstruction is not influenced by the input patch and the defects therein and, thus, can be more accurate.

According to an example, defects can be detected directly in a feature space of the trained Vision Transformer. To this end, the trained Vision Transformer can be used to map a masked patch to a feature representation. Defects can then be detected using a trained defect detection method that works in the feature space of the trained Vision Transformer. For example, a defect segmentation method can be trained in the feature space.

In a preferred example, the input to the machine learning model, in particular to a Vision Transformer, additionally comprises one or more meta tokens representing meta information concerning the imaging dataset and/or the imaging device used to obtain the imaging dataset. The meta information can be from the group comprising integrated circuit pattern type (e.g. memory or logic), half-pitch, structure size in the integrated circuit pattern, defect size, location in the object, defocus, sharpness, brightness, exposure, noise level, light source properties, imaging device properties, etc. By using one or more meta tokens as input to the machine learning model, additional information on the imaging dataset and/or the image acquisition process can be easily provided to the machine learning model, thereby improving the accuracy of the predictions in a simple way. Furthermore, by indicating meta information, a single machine learning model can be used for different types of imaging datasets or applications instead of having to train separate machine learning models for each type of imaging dataset or application. Thus, the machine learning model is easily adaptable, and user effort and memory requirements are reduced.

According to an embodiment of the invention, a computer implemented method for training a machine learning model for defect highlighting for use in any of the methods for defect detection described above, comprises: providing training images of objects comprising integrated circuit patterns; and training the machine learning model for defect highlighting using the provided training images by minimizing a loss function configured for highlighting defects. The loss function can, for example, compare the highlighted defects in the training images to the highlighted defects computed by the machine learning model for defect highlighting. Based on the value of the loss function, the parameters of the machine learning model can be iteratively updated until convergence. In case of a neural network, a backpropagation algorithm or any of its variants can be used.

According to an embodiment of the invention, a computer implemented method for training a Vision Transformer machine learning model as described above comprises: providing training images of objects comprising integrated circuit patterns; partitioning each training image into patches; training the Vision Transformer machine learning model by iteratively presenting one or more training images to the Vision Transformer machine learning model, wherein one or more of the patches of each training image are masked, and modifying the parameters of the Vision Transformer machine learning model by minimizing a loss function configured for highlighting defects. The loss function can, for example, compare the annotated defects in the training images to the highlighted defects computed by the Vision Transformer. Based on the value of the loss function, the parameters of the Vision Transformer can be iteratively updated until convergence. In case of a neural network, a backpropagation algorithm or any of its variants can be used.

According to a preferred embodiment, the patches are defined using meta information from the group comprising critical dimension, relevant and/or irrelevant locations, structures or structure types, design information of the object comprising integrated circuit patterns. Critical dimensions can be used to define patch sizes. The relevance of locations, structures or structure types can be used to suitably weight the loss function, e.g., by putting higher weight to relevant locations, structures or structure types or lower weight to irrelevant locations, structures or structure types. Design information comprise, for example, the location of structures in the object in the form of polygons. Thus, the division of defects by patch boundaries can be prevented or reduced, such that a defect lies within a single patch or within as few patches as possible. In this way, the Vision Transformer is prevented from reconstructing a defect in the imaging dataset from a part of the defect contained in one or more neighboring patches. Thus, the machine learning task is simplified, and the accuracy of the detected defects is improved.

According to an example, the machine learning model for defect highlighting computes a reconstruction of the imaging dataset, and the loss function comprises a deviation of the reconstruction from the imaging dataset. Defects can then be detected by comparing the reconstruction of the imaging dataset to the reference dataset. Since the defects are highlighted in the reconstruction of the imaging dataset, the accuracy of the defect detection is improved. Furthermore, the detection of defects is simplified and requires less accurate decision criteria or algorithms for identifying defects in the comparison.

In a preferred example, the training images comprise annotated defects. In this way, the loss function can discriminate between defective regions and defect-free regions, thereby improving the accuracy of the trained machine learning model.

According to an aspect, the loss function applies a higher penalty to deviations of the reconstruction from the imaging dataset within defective regions than within defect-free regions. In this way, defects are reconstructed with high accuracy, such that they can be easily detected when comparing the reconstructed imaging dataset to the reference dataset. Furthermore, details of the defects are reconstructed and, thus, preserved in the defect detection. Thus, the accuracy of the detected defects is improved.

In an example, the loss function is configured to highlight features within the defective regions. In this way, the deviation of the reconstructed imaging dataset from the reference dataset is increased within defects, and the defects can be detected more easily. In addition, specific features of the defects are preserved, e.g., features that are particularly relevant for classifying a defect. Thus, the accuracy of the detected defects is improved.

In an example, the loss function is configured to modify properties of the imaging dataset within defective regions. A defective region is a local region of the imaging dataset comprising a defect, e.g., a bounding box. Properties of the imaging dataset include, for example, brightness, contrast, intensity, color, focus, sharpness, distortions, noise, etc. In this way, the deviation of the reconstructed imaging dataset from the reference dataset is increased within defects, and the defects can be detected more easily. Thus, the accuracy of the detected defects is improved.

According to a preferred example, the majority of defects in the training images are weakly annotated. A weak annotation of a defect refers to an annotation that comprises pixels that do not belong to the defect and/or that does not contain all pixels that belong to the defect. Weak annotations comprise, for example, bounding boxes of any shape and size, one or more points of a defect, e.g., a center point or edge points, partial annotations comprising a subset of the pixels of the defect, circumcircles, etc. In this way, the user effort for training the machine learning model is strongly reduced as annotations do not have to be exact.

According to an embodiment of the invention, a computer program comprising instructions which, when the program is executed by a computer, cause the computer to carry out a method of any of the methods for defect detection described above.

A computer-readable medium, according to an embodiment of the invention, has a computer program executable by a computing device stored thereon, the computer program comprising code for executing a method of any of the methods for defect detection described above.

A system for defect detection according to an embodiment of the invention comprises: an imaging device configured to provide an imaging dataset of an object comprising integrated circuit patterns; one or more processing devices; and one or more machine-readable hardware storage devices comprising instructions that are executable by one or more processing devices to perform operations comprising any of the methods for defect detection described above.

The invention described by examples and embodiments is not limited to the embodiments and examples but can be implemented by those skilled in the art by various combinations or modifications thereof.

### BRIEF DESCRIPTION OF THE DRAWINGS

FIG. 1 illustrates an exemplary transmission-based photolithography system, e.g., a deep ultraviolet (DUV) photolithography system;

FIG. 2 illustrates an exemplary reflection-based photolithography system, e.g., an extreme ultraviolet (EUV) photolithography system;

FIG. 3 shows an imaging dataset of an object comprising integrated circuit patterns in the form of a photolithography mask comprising a defect;

FIG. 4 illustrates a flowchart of a computer implemented method for defect detection according to an embodiment of the invention;

FIG. 5A illustrates an exemplary implementation of an attention mechanism in a machine learning model;

FIG. 5B illustrates a Transformer block comprising multiple attention mechanisms;

FIG. 6-9 illustrate the detection of defects according to different embodiments of the invention;

FIG. 10 illustrates an attention mechanism within a convolutional neural network;

FIG. 11 illustrates the structure of a U-Net comprising attention mechanisms;

FIG. 12 illustrates the structure of a Vision Transformer comprising attention mechanisms;

FIG. 13 illustrates a defect detection method for objects comprising integrated circuit patterns using masked autoencoding;

FIG. 14 illustrates a system for defect detection in an object comprising integrated circuit patterns according to an embodiment of the invention.

### DETAILED DESCRIPTION

In the following, advantageous exemplary embodiments of the invention are described 25 and schematically shown in the figures. Throughout the figures and the description, same reference numbers are used to describe same features or components. Dashed lines indicate optional features.

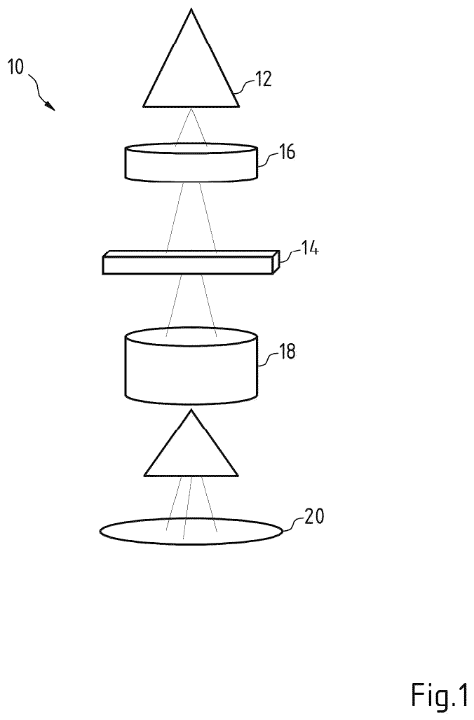

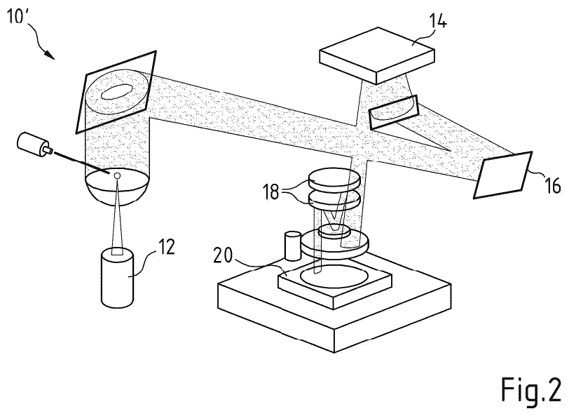

The methods described herein can be used, for example, with transmission-based 30 photolithography systems 10 or reflection-based photolithography systems 10′ as shown in FIGS. 1 and 2.

FIG. 1 illustrates an exemplary transmission-based photolithography system 10, e.g., a DUV photolithography system. Major components are a light source 12, which may be a deep-ultraviolet (DUV) excimer laser source, imaging optics which, for example, may include optics that shape radiation from the light source 12, a photolithography mask 14, illumination optics 16 that illuminate the photolithography mask 14 and projection optics 18 that project an image of the photolithography mask pattern onto a photoresist layer of a wafer 20. An adjustable filter or aperture at the pupil plane of the projection optics 18 may restrict the range of beam angles that impinge on the wafer 20.

In the present document, the terms “radiation” or “beam” are used to encompass all types of electromagnetic radiation, including ultraviolet radiation (e.g., with a wavelengths of 365, 248, 193, 157 or 126 nm) and EUV (extreme ultra-violet radiation, e.g. having a wavelength in the range of about 3-100 nm).

Illumination optics 16 may include optical components for shaping, adjusting and/or projecting radiation from the light source 12 before the radiation passes the photolithography mask 14. Projection optics 18 may include optical components for shaping, adjusting and/or projecting the radiation after the radiation passes the photolithography mask 14. The illumination optics 16 exclude the light source 12, the projection optics exclude the photolithography mask 14.

Illumination optics 16 and projection optics 18 may comprise various types of optical systems, including refractive optics, reflective optics, apertures and catadioptric optics, for example. Illumination optics 16 and projection optics 18 may also include components operating according to any of these design types for directing, shaping or controlling the projection beam of radiation, collectively or singularly.

FIG. 2 illustrates an exemplary reflection-based photolithography system 10′, e.g., an extreme ultraviolet light (EUV) photolithography system 10′. Major components are a light source 12, which may be a laser plasma light source, illumination optics 16 which, for example, may include optics that shape radiation from the light source 12, a photolithography mask 14, and projection optics 18 that project an image of the photolithography mask pattern onto a photoresist layer of a wafer 20. An adjustable filter or aperture at the pupil plane of the projection optics 18 may restrict the range of beam angles that impinge on the wafer 20.

The production of objects comprising integrated circuit patterns such as photolithography masks, reticles and wafers requires great care due to the small structure sizes of the integrated circuit patterns. Defects cannot be prevented but can lead to the malfunctioning of semiconductor devices. Therefore, an accurate and fast method for defect detection in objects comprising integrated circuit patterns is important.

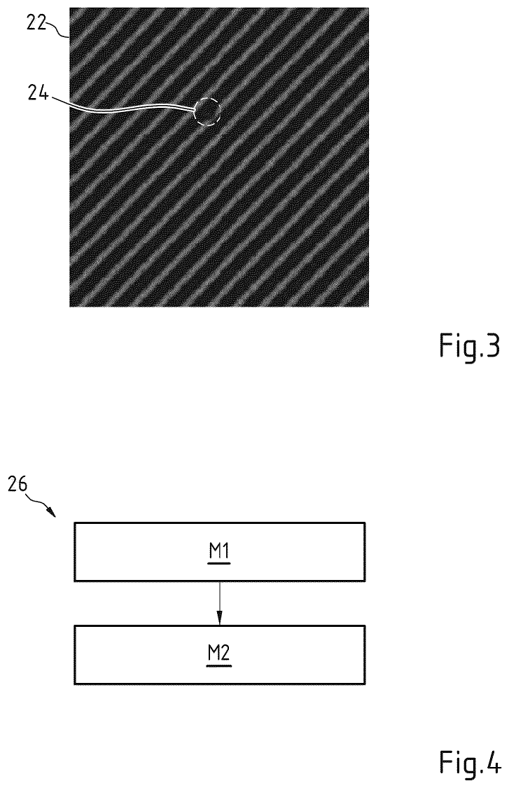

FIG. 3 shows an imaging dataset 22 of an object comprising integrated circuit patterns in the form of a photolithography mask 14 comprising a defect 24. Methods known from the art often use die-to-die or die-to-database methods to detect such defects 24. Die-to-die methods compare a portion of the imaging dataset 22 to another portion of the same or a different imaging dataset 22 to detect defects 24. However, the applicability of die-to-die methods is limited, e.g., repeater defects cannot be discovered and suitable portions for comparison have to be found. In addition, they require the availability and time-consuming scanning of two corresponding portions of the object and exact knowledge about their relative position. Furthermore, the reference image can, nevertheless, contain defects. In contrast, die-to-database methods allow for the detection of any defect 24 by providing a reference dataset that can be directly compared to an imaging dataset 22 of the object comprising integrated circuit patterns. Due to the large amount of data to be compared, machine learning methods can be used to analyze the data automatically and quickly. However, convolutional neural networks that are commonly used for this task heavily rely on the concept of local convolutions with fixed weights derived from training data. Therefore, only local context can be taken into account by the CNN to detect defects. Furthermore, the fixed weights of the convolutions limit the learning capacity of the CNN. Therefore, it is an aspect of the invention to provide defect detection methods for objects comprising integrated circuit patterns with improved accuracy.

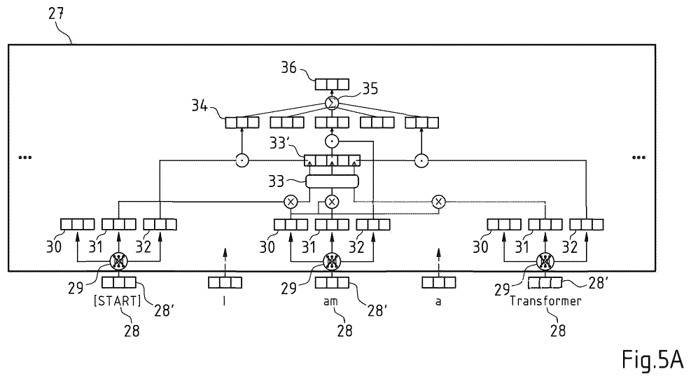

FIG. 4 illustrates a flowchart of a computer implemented method 26 for defect detection in an imaging dataset of an object comprising integrated circuit patterns according to an embodiment of the invention. The method comprises: obtaining an imaging dataset and a reference dataset of an object comprising integrated circuit patterns in a step M1; detecting defects in the imaging dataset using the imaging dataset and the reference dataset, wherein a machine learning model for defect highlighting is applied to the imaging dataset as input and generates a highlighted defect dataset as output, and wherein the machine learning model for defect highlighting comprises at least one attention mechanism, in a step M2.

Attention mechanisms in deep learning are used to help the model focus on the most relevant parts of an input when making a prediction. In many problems, the input may be very large and complex, and it can be difficult for the model to process all of it. Therefore, attention mechanisms allow the model to selectively focus on the parts of the input that are most important for making a prediction, and to ignore the less relevant parts. This can help the model to make more accurate predictions and to run more efficiently at reduced computation time. As an example, attention mechanisms can be used to analyze text data or audio data (which is sequential), image data (which is spatially ordered as a 2D matrix or 3D matrix), or graph data (which is spatially un-ordered).

The attention mechanism helps preserve the context of every section in an input by assigning an attention weight relative to many or even to all other sections. This way, even if the input is large, the model can preserve the contextual importance of each section.

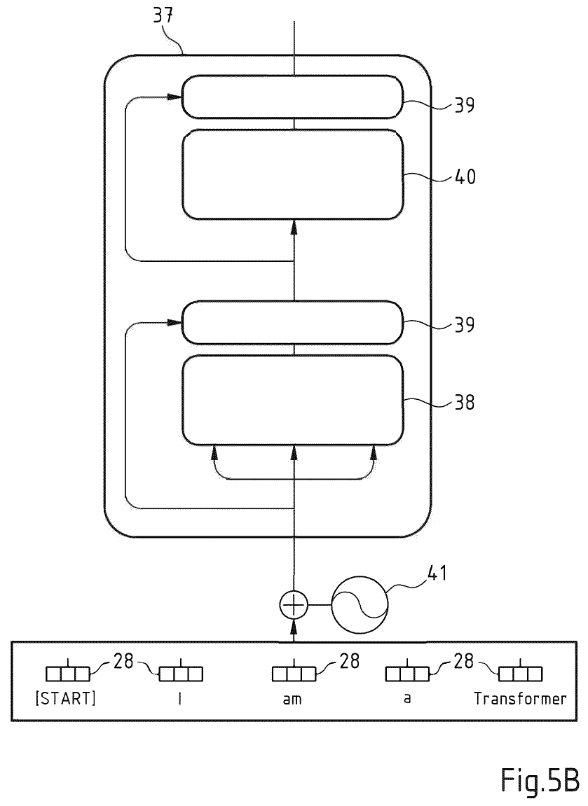

Attention mechanisms 27 can be configured as a specific kind of neural network layer illustrated in FIG. 5A that can be added to deep learning models. They allow the model to focus on specific parts of the input by assigning different weights to different parts of the input. This weighting is typically based on the relevance of each part of the input to the task at hand.

The attention mechanism 27 processes individual parts (called “token” 28) of the input. For example, tokens 28 can be words, sub-words, or characters as part of a text, patches or pixels as part of an image or derived representations or image features. The processing of each token 28 considers local or global context, possibly even the entire input, or context from a second data source. This contrasts with, e.g., convolutional filters in CNNs, which always focus on local context only. The “amount of” context which is considered and the processing operations for this consideration depend both on the current token 28. This also contrasts with convolution filters in CNNs, which have fixed size and fixed weights (i.e., fixed operations for each local structure) after being trained.

During the processing, the attention mechanism 27 transforms a representation in the form of a feature vector 28′ of a token 28 into an attention-based representation 36 while considering local or global context. The attention-based representation is an aggregation of values derived from multiple tokens 28, weighted by the result of a comparison between these tokens 28 and the one currently being processed, or between derived feature vectors 28′ or further derived representations.

Attention mechanisms 27 comprise self-attention mechanisms and cross-attention mechanisms. Self-attention mechanisms transform the input to a new representation of the input called attention-based representation 36, thereby paying attention to different sections of the input itself. Cross-attention mechanisms transform the input into the new representation called attention-based representation 36 by paying attention to another data source. For example, the other data source can be a sentence in a first language that is paid attention to while consecutively translating each of the words into a second language.

A possible realization of a self-attention mechanism as illustrated in FIG. 5A can be described as follows: let T⊂ [symbol] denote a set of tokens 28 represented by multivariate feature vectors 28′ of dimensionality D_{T}. The attention mechanism 27 a: [symbol] → [symbol] transforms those representations into attention-based representations 36 using a similarity function 33 s: [symbol] × [symbol] → [symbol] yielding an attention distribution 33′ as a result, and an aggregation function 35 m: [symbol] ( [symbol] )→ [symbol] :

$$a ( t ) = m ( \{ s ( q ( t ) , k ( u ) ) \cdot v ( u ) \vert u ∈ T \} )$$

that maps attention weighted values 34 to attention-based representations 36 of the input tokens 28. Here, [symbol] denotes the power set. The functions q: [symbol] → [symbol] , k: [symbol] → [symbol] , and v: [symbol] → [symbol] are local feature transformations called query, key and value function that map a token t to a so-called query 30, key 31 and value 32. The query, key and value function can, for example, comprise a trainable parameter, e.g., one or more projection matrices. The comparison function s measures the similarity between the query 30 q(t) for the current token t and the key 31 k(u) for all tokens u∈T. Thus, similarities between different tokens in the input can be measured by the function s. The value 32 can be understood as a representation of the token t. The aggregation function m, thus, aggregates all values of the input weighted by their similarity to the query of the current token t. Thus, instead of using fixed values as weights as in case of convolutions, the weights depend on the input data (tokens).

An example for an attention mechanism called “scaled dot-product attention” or “softmax attention” defines the similarity function and the aggregation function as follows:

$$s ( t , u ) = \frac{exp ( 〈 t , u 〉 / \sqrt{{d}_{k}} )}{{\sum }_{{u}^{′} ∈ T} exp ( 〈 t , {u}^{′} 〉 / \sqrt{{d}_{k}} )} , \qquad m ( X ) = {\sum }_{x ∈ X} x .$$

In this implementation, the functions k, q, v are typically realized by a learned linear transformation (projection matrices) or a small multilayer perceptron. Further attention mechanisms can also be used, e.g., “additive attention” or “not-scaled dot-product attention.” The aforementioned attention mechanisms are described in “Attention is all you need, A. Vaswani, N. Shazeer, N. Parmar, J. Uszkoreit, L. Jones, A. Gomez, L. Kaiser, I. Polosukhin, Advances in Neural Information Processing Systems, vol. 30. 2017”.

Similarly, a cross-attention mechanism can be implemented. In this case, two sets of tokens 28 T⊂ [symbol] and U⊂ [symbol] are given. For example, in case of language translation T and U represent the tokens of each language stream. The attention mechanism 27 a: [symbol] → [symbol] is defined as follows:

$$a ( t ) = m ( \{ s ( q ( t ) , k ( u ) ) \cdot v ( u ) \vert u ∈ U \} )$$

using the query, key and value functions k: [symbol] → [symbol] , q: [symbol] → [symbol] , and v: [symbol] > [symbol] In this case, the query q(t) of a token 28 in T is compared to all keys 31 obtained from the tokens 28 in set U. Thus, the attention-based representation 36 of token t depends on the second set of tokens U, thereby implementing cross-attention.

In case the attention mechanism involves learned parameters, multiple attention mechanisms 27 with different learned parameters can be applied to the same input tokens and the attention-based representation 36 can be concatenated for further processing. This process is called multi-head attention mechanism.

Using attention mechanisms 27 has the following advantages: first, the attention-based representations 36 of the tokens 28 take into account relationships between tokens 28 from the entire input sequence instead of only from a local neighborhood as, for example, in a CNN. Second, the processing operations applied to the tokens 28 depend on the tokens instead of being fixed as, for example, in convolutions of CNNs.

Attention mechanisms are typically used as one building block combined with other operations, for example in a Transformer block 37 as illustrated in FIG. 5B. The Transformer block 37 uses an input comprising a set of tokens 28 and positional encodings 41 that encode the position of each token within the input sequence. A multi-head attention mechanism 38 comprising multiple attention mechanisms 27 transforms the input to an attention-based representation 36 of the input. In an add & norm layer 38 the input is added to the attention-based representation 36 in order to prevent vanishing gradients during training, and the result is normalized to improve convergence of the model. A feed-forward neural network 40 is applied to transform the result into a form that can be used by the following layer. Compared to an attention mechanism, a Transformer block, therefore, provides for more stable learning due to the normalization in the add & norm layer and allows for further non-linearities by use of the feed-forward neural network 40. Thus, more accurate predictions are achieved.

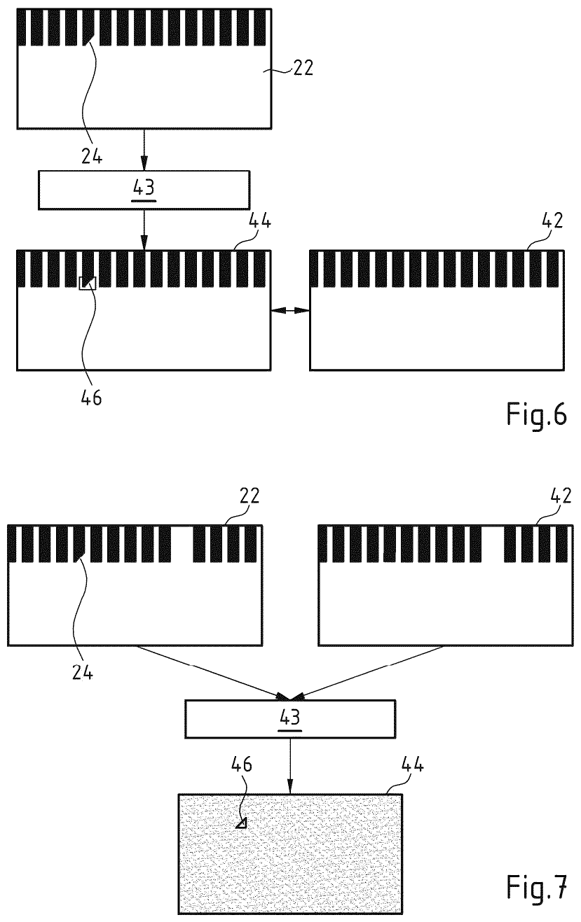

FIG. 6 illustrates the detection of defects 24 according to an embodiment of the invention. An imaging dataset 22 of an object comprising integrated circuit patterns, e.g., a photolithography mask or wafer, is acquired. The imaging dataset 22 contains a defect 24. A trained machine learning model for defect highlighting 43 that includes at least one attention mechanism 27 is applied to the imaging dataset 22 to obtain a highlighted defect dataset 44. The machine learning model for defect highlighting 43 amplifies the defects 24 in the input. The highlighted defect dataset 44 comprises the highlighted defect 46. To highlight the defect 24, properties of the defective region were modified, in this case the intensity and the contrast of a bounding box comprising the defect 24. The defect 24 can be detected by comparing the highlighted defect dataset 44 to a reference dataset 42, e.g., by computing a difference image. The difference image can be thresholded to detect defects, or other methods can be used for defect detection, e.g., a machine learning model can be trained to extract defects from the difference image or from the highlighted defect dataset 44 and the reference dataset 42.

FIG. 7 illustrates the detection of defects 24 according to an embodiment of the invention. An imaging dataset 22 of an object comprising integrated circuit patterns, e.g., a photolithography mask or wafer, is acquired. The imaging dataset 22 contains a defect 24. A reference dataset 42 is obtained, e.g., by extracting polygons from a CAD file. The imaging dataset 22 and the reference dataset 42 are used as inputs to the machine learning model for defect highlighting 43 that includes at least one attention mechanism. Thus, the reference dataset 42 is used as additional input to the machine learning model for defect highlighting 43. The machine learning model for defect highlighting 43 generates a highlighted defect dataset 44 in the form of a segmentation of the imaging dataset 22. The segmentation includes a highlighted defect 46 comprising intensities above a specific threshold, e.g., above 0 or higher. The defect can be obtained using thresholding or defect detection algorithms, e.g., contour detection methods or machine learning algorithms.

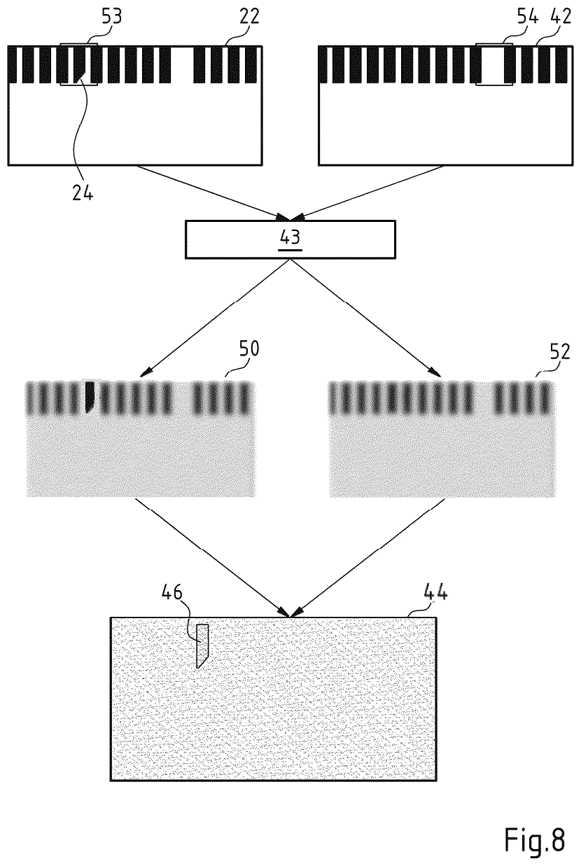

FIG. 8 illustrates the detection of defects 24 according to an embodiment of the invention. An imaging dataset 22 of an object comprising integrated circuit patterns, e.g., a photolithography mask or wafer, is acquired. The imaging dataset 22 contains a defect 24. A reference dataset 42 is obtained, e.g., by generating polygons from a CAD file. The imaging dataset 22 and the reference dataset 42 are used as inputs to the machine learning model for defect highlighting 43 that includes at least one attention mechanism. Thus, the reference dataset 42 is used as additional input to the machine learning model for defect highlighting 43. The machine learning model for defect highlighting 43 is trained to reconstruct the imaging dataset 22 and the reference dataset 42. The machine learning model for defect highlighting 43, thus, computes a reconstruction of the input 50 including the defects 24. It also computes a reconstruction of the reference dataset 52. The machine learning model for defect highlighting 43 reconstructs defective regions 53 in the input with a higher accuracy than defect-free regions 54. This can be accomplished by designing the loss function for training of the machine learning model for defect highlighting 43 such that deviations in the reconstruction of defects 24 are weighted higher than deviations in the reconstruction of defect-free regions 54. For this reason, the reconstruction of the imaging dataset 50 is blurry within defect-free regions 54, in particular along edges, while the defect is reconstructed clearly. The reconstruction of the reference dataset 52 is also blurry within defect-free regions 54, that is everywhere. The highlighted defect dataset 44 is obtained by comparing the reconstruction of the imaging dataset 50 to the reconstruction of the reference dataset 52, e.g., by computing the difference image.

Since the reconstruction of the imaging dataset 50 and the reconstruction of the reference dataset 52 is blurry within regions without defects 54, the difference is close to 0, whereas the difference is large for defects 24.

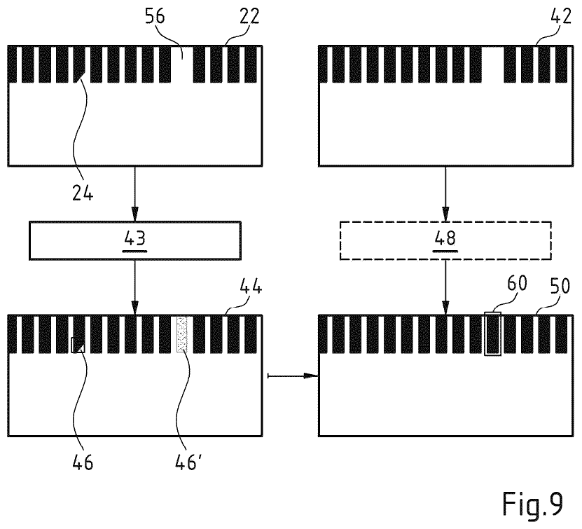

FIG. 9 illustrates the detection of defects 24 according to an embodiment of the invention. An imaging dataset 22 of an object comprising integrated circuit patterns, e.g., a photolithography mask or wafer, is acquired. The imaging dataset 22 contains a defect 24. A reference dataset 42 is obtained, e.g., by generating polygons from a CAD file. The imaging dataset 22 is used as input of a trained machine learning model for defect highlighting 43. The machine learning model for defect highlighting amplifies the defects 24, thereby generating highlighted defects 46. Due to the irregular circuit pattern, it also amplifies the absent structure 56, thereby generating a highlighted defect 46′. The absent structure 56 can be a defect, but it can also be due to an irregularity in the design. For this reason, the reference dataset 42 is used that contains the correct design. The reference dataset 42 can, optionally, be used as input of a further machine learning model 48. The further machine learning model contains at least one attention mechanism 27. The further machine learning model 48 transforms the reference dataset 42. For example, the transformation of the reference dataset 42 can regularize the design, e.g., by adding the absent structure 56. By comparing the regularized reference dataset 58 to the imaging dataset, e.g., by computing a difference image, regions with irregular structures 60 can be identified. Defect detection methods are likely to generate false positive defect detections in these regions with irregular structures 60. Therefore, these regions with irregular structures 60 can be ignored in the defect dataset 44. In this way, the highlighted defect 46′ due to the absent structure 56 is ignored, since it lies within the region with irregular structures 60 that is ignored for defect detection. The other highlighted defect 46 does not lie within a region with irregular structures 60 and is, thus, marked as defect 24.

In an alternative example, the further machine learning model can be used to adapt the appearance of the reference dataset 42 to the appearance of the imaging dataset 22 to make both comparable in order to improve the defect detection. For example, in case the reference dataset 42 is obtained from a model of the object comprising integrated circuit patterns, e.g., from a CAD file, or some other simulated dataset, adapting the appearance of the reference dataset 42 is beneficial before comparing the imaging dataset 22 to the reference dataset 42. In this case, the further machine learning model can be a generative adversarial neural network (GAN) comprising a generator that is trained to imitate the appearance of the imaging dataset and a discriminator that is trained to discriminate between real reference datasets and imitated reference datasets.

After training, the generator can be applied to the reference dataset 42 to imitate the appearance of the imaging dataset 22, e.g., the defocus or noise level of the imaging dataset.

The machine learning model for defect highlighting 43 including an attention mechanism can be designed in different ways. These designs can be used in the examples in FIG. 6, 7, 8 or 9.

In an example, the machine learning model for defect highlighting 43 comprises a convolutional neural network (CNN) that contains at least one attention mechanism 27.

The attention mechanism 27 increases the receptive field of the CNN to the whole input image without adding computational cost associated with very large kernel sizes.

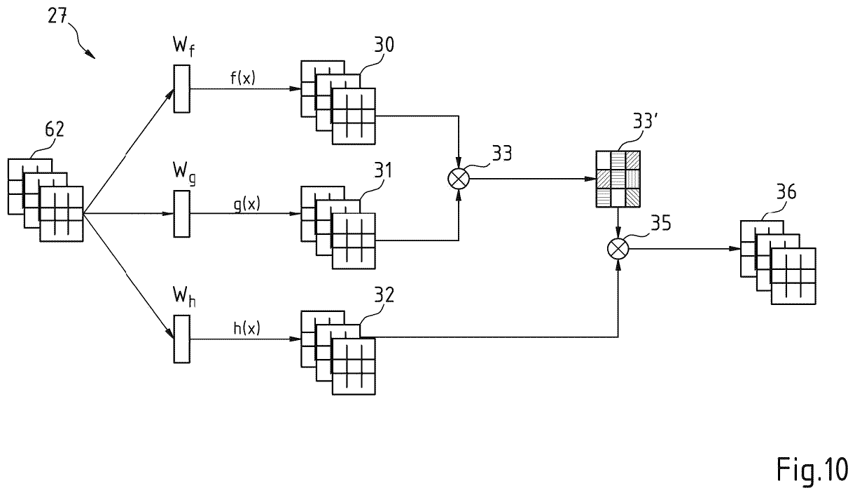

Referring to FIG. 10, let x∈ [symbol] indicate convolution feature maps 62 obtained from a previous layer of the CNN, wherein C is the number of channels and N is the product of all other dimensions. The query, key and value functions q, k, v apply projection matrices W_{q}, Wₖ, Wᵥ∈ [symbol] that are trainable parameters:

$$q ( x ) = {W}_{q} x , \qquad k ( x ) = {W}_{k} x , \qquad v ( x ) = {W}_{v} x .$$

The attention function a maps each pixel vector xᵢ∈ [symbol] to a new attention-based representation 36 that takes into account the other pixels xⱼ∈ [symbol] of the input. The attention function can be defined as

$$a ( {x}_{i} ) = m \{ s ( q ( {x}_{i} ) , k ( {x}_{j} ) ) \cdot v ( {x}_{j} ) \}$$

using a softmax similarity function 33

$$s ( {x}_{i} , {x}_{j} ) = \frac{exp ( {q ( {x}_{i} )}^{T} k ( {x}_{j} ) )}{{\sum }_{k = 1}^{N} {q ( {x}_{i} )}^{T} k ( {x}_{k} )}$$

and an aggregation function 35

$$m ( Y ) = {\sum }_{y ∈ Y} y .$$

Thus, the attention function maps each pixel vector to the following attention-based representation 36:

$$a ( {x}_{i} ) = {\sum }_{j = 1}^{N} s ( {x}_{i} , {x}_{j} ) \cdot v ( {x}_{j} ) .$$

The similarities s(xᵢ,xⱼ) are called attention distribution 33′ and quantify the importance of pixel vectors xⱼ in the input relative to the pixel vector xᵢ in the input. Since the similarities s(xᵢ,xⱼ) are computed over large parts or even the entire width and height of the convolution feature maps 62, the receptive field is not limited to the size of a small kernel anymore. The output has the same number of channels as the input convolution feature maps 62. C* can, for example, be set to C/8. The given similarity and aggregation functions are only examples. Other functions known to a person skilled in the art can be used as well.

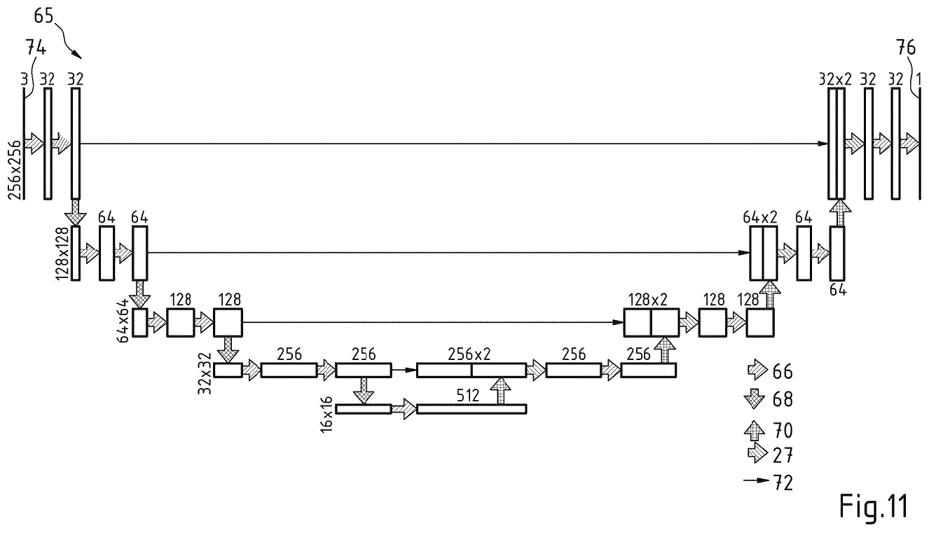

The CNN containing at least one attention mechanism 27, can, for example, comprise a U-Net 65 as illustrated in FIG. 11. The U-Net 65 comprises different operations that are applied to the input data 74 to generate the output data 76. The numbers next to each layer indicate the layer size. The operations comprise conv 3×3 batch norm operations 66, max pool 2×2 operations 68, up-conv 2×2 operations 70, attention mechanisms 27 comprising conv 3×3 batch norm operations and copy and concatenate operations 72. An example for using a U-Net 65 with attention mechanism 27 for anomaly detection is given in “Masked Swin Transformer Unet for Industrial Anomaly Detection, Jielin Jiang, Jiale Zhu, Muhammad Bilal, Yan Cui, Neeraj Kumar, Ruihan Dou, Feng Su, Xiaolong Xu, IEEE Transactions on Industrial Informatics, Vol. 19, No. 2, 2023.”

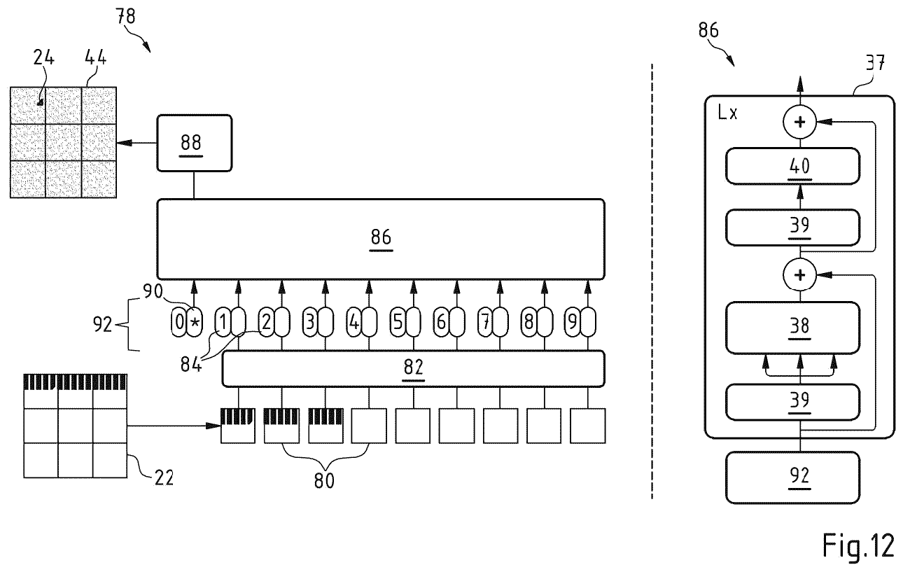

In an example, the machine learning model for defect highlighting 43 comprises a vision transformer (ViT) 78 illustrated in FIG. 12. The ViT is described in the paper “An Image is Worth 16×16 Words: Transformers for Image Recognition at Scale, Alexey Dosovitskiy, Lucas Beyer, Alexander Kolesnikov, Dirk Weissenborn, Xiaohua Zhai, Thomas Unterthiner, Mostafa Dehghani, Matthias Minderer, Georg Heigold, Sylvain Gelly, Jakob Uszkoreit, Neil Houlsby, CoRR, 2020.” The ViT receives a sequence of N flattened 2D patches 80 obtained by partitioning the imaging dataset 22. The sequence of flattened patches 80 is embedded using a linear projection whose parameters are learned during training of the ViT 78. The embedded patches are combined with a positional encoding 84 that encodes the location of each patch 80 within the imaging dataset 22. Different kinds of positional encodings 84 can be used, e.g., 1D positional encodings, 2D positional encodings or relative positional encodings. The positional encodings can be modeled, e.g., using oscillating functions such as sine and/or cosine functions, that can have different frequencies, or they can be learned. For example, techniques based on p. 6 section 3.5 of the publication “A. Vaswani et al., Attention Is All You Need, 2017, Advances in Neural Information Processing Systems 30 (NIPS 2017), pp. 6000-6010 (https://arxiv.org/abs/1706.03762)” can be used. Positional encodings can be learned or predetermined. When learning the positional encodings, the positional encodings may be trained along with the transformer.

The combination of patch and position embedding 92 for each patch 80 is used as input to the first of a sequence of L Transformer blocks 37 constituting the transformer-encoder 86. In addition, one or more meta tokens 90 are added to the input sequence that can contain meta information concerning the imaging dataset and/or the imaging device 116 used to obtain the imaging dataset 22, e.g., the type of integrated circuit patterns (e.g., memory or logical), the exposure time, etc. Each of the Transformer Encoder blocks 37 comprises an attention mechanism 27 within the multi-head attention 38 block. Each of the Transformer Blocks 37 receives a sequence of patch and position embeddings 92 as input (either the input sequence or the result of the preceding Transformer block 37, optionally processed, embedded or spatially encoded) and applies a sequence of transformations comprising an add & norm layer 39, multi-head attention 38, and a feed-forward neural network 40 at the end. To obtain a highlighted defect dataset 44 in form of a segmentation of the defects the result is processed by a decoder 88, which decodes each single encoded representation of a patch. The decoded patches are combined to obtain the highlighted defect dataset 44. The highlighted defect dataset indicates a defect 24.

Many different variants of decoders are conceivable. For example, the decoder can comprise a multilayer perceptron neural network that maps an encoded representation of a patch to a decoded patch of the original size. Alternatively, a CNN decoder could be used with successive upsampling stages. Alternatively, the decoder can comprise a second Transformer in order to take into account the other encoded patches as context during the decoding process.

A variational autoencoder (VAE) can be added between the final Transformer Block 37 and the decoder 88 as, for example, described in “ViV-Ano: Anomaly Detection and Localization Combining Vision Transformer and Variational Autoencoder in the Manufacturing Process, Byeonggeun Choi and Jongpil Jeong, Electronics 2022, 11, 2306.” The VAE has the advantage that it allows to sample multiple reconstructions of the imaging dataset. This in turn allows to compute, for example, a mean reconstruction and a standard deviation of multiple reconstructions. The mean reconstruction can be used as a reconstruction of the imaging dataset, whereas the standard deviation can be used as a confidence measure.

In a preferred example, the ViT 78 is pre-trained using masked autoencoding. Masked autoencoding means that one or more patches of the imaging dataset are iteratively masked and reconstructed by the ViT 78. The loss function penalizes deviations of the reconstructed patches from the patches of the imaging dataset 22. A highlighted defect dataset 44 can be obtained by reconstructing each of the patches by use of the ViT 78. Defects can then be detected by comparing the highlighted defect dataset 44 to the imaging dataset 22. A masked autoencoder is described, for example, in “MCMAE: Masked convolution meets masked autoencoders, Peng Gao, Teli Ma, Hongsheng Li, Ziyi Lin, Jifeng Dai, Yu Qiao, NeurIPS 2022.”

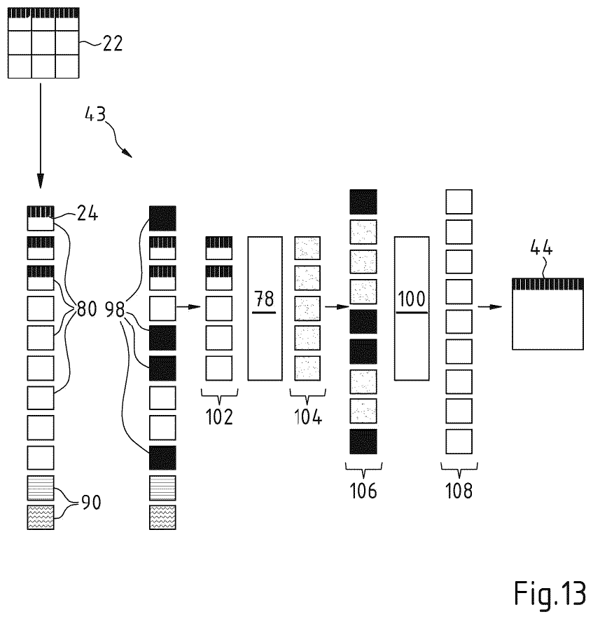

In particular, detecting defects 24 using masked autoencoding comprises the following steps illustrated in FIG. 13. First, the imaging dataset 22 of the object comprising integrated circuit patterns is partitioned into a set of patches 80. One or more of the patches 80 of the imaging dataset 22 are iteratively masked, thereby generating a set of one or more masked patches 98 in each step. A Vision Transformer 78 machine learning model is applied to encode the unmasked patches 102 generating encoded patches 104. Then a decoder 100 is applied to the combined patches 106 comprising the encoded patches 104 and the one or more masked patches 98 in order to reconstruct the one or more masked patches 98. The generated decoded patches 108 are combined to obtain a highlighted defect dataset 44 in the form of a reconstructed imaging dataset. Defects can then be detected by comparing the imaging dataset to the highlighted defect dataset 44, e.g., by using a difference image or a trained machine learning model.

In an example, the trained Vision Transformer 78 can be used as a pre-trained encoder for encoding an imaging dataset 22 with highlighted defects. A defect detection method can then be trained using the encoded imaging datasets 22 as input to obtain defect detection results with higher accuracy. In another example, the trained Vision Transformer 78 can be used to initialize the parameters of an encoder.

In another example, a machine learning model comprising two input branches can be used for defect detection. The first input branch processes the imaging dataset 22, the second input branch the reference dataset 42. The first and the second input branch can comprise an encoder. A trained Vision Transformer 78 can be used as initialization of the parameters of one or both of the encoders. The two input branches converge at some point of the machine learning model. The following layers are trained to generate an output map, e.g., a defect segmentation map or a defect detection map, from the encoded imaging dataset 22 and the encoded reference dataset 42.

According to an aspect of the invention, the input to the Vision Transformer 78 machine learning model additionally comprises one or more meta tokens 90 representing meta information concerning the imaging dataset and/or the imaging device 116 used to obtain the imaging dataset 22. The meta information can, for example, be from the group comprising pattern type, half-pitch, structure size, defect size, location in the object, defocus, brightness, exposure, noise level, light source properties, imaging device properties. By using meta information of this kind, the reconstruction task can be simplified. For example, the pattern type, the half-pitch and the structure size all contain information on the expected dimensions of the structures in the imaging dataset, and, thus, on the size of the expected defects. The defect size contains information on the size of defects that are deemed relevant. Very small defects can, for example, be ignored in this way. The location in the object comprising integrated circuit patterns can, for example, be used to identify irrelevant regions or highly relevant regions or to help in the detection of defects. For example, the machine learning model for defect highlighting 43 can learn typical or probable defect locations in the object comprising integrated circuit patterns or locations that are usually defect-free. Information on the appearance or quality of the imaging dataset such as defocus, brightness, exposure or noise can improve the defect detection results, since the Vision Transformer can be trained to generate different outputs depending on the appearance or quality of the imaging dataset. Light source and imaging device properties can also contain additional information on the appearance of the structures and defects in the imaging dataset 22 that can be used by the Vision Transformer to improve the defect detections.

Defects in an imaging dataset can also be detected using a reconstruction-based machine learning model. A reconstruction-based machine learning model receives an imaging dataset as input and reconstructs this imaging dataset. The reconstruction-based machine learning model preferably comprises at least one attention mechanism.

By comparing the imaging dataset to the reconstructed imaging dataset defects can be detected.

A computer implemented method for training a machine learning model for defect highlighting according to any of the previously described embodiments comprises: providing training images of objects comprising integrated circuit patterns, the training images comprising annotated defects; and training the machine learning model for defect highlighting using the provided training images by minimizing a loss function configured for highlighting defects. Different loss functions can be used for highlighting defects 24. For example, the loss function can comprise a deviation of the detected defects from the annotated defects, e.g., an intersection over union measure, a pixel-wise difference, the deviation of the center points, the deviation of the size, etc. The loss function can penalize deviations of the highlighted defect dataset 44 from a ground truth highlighted defect dataset obtained from the training images and the annotated defects. Deviations within defective regions 53 can be penalized higher than deviations within regions without defects.

A computer implemented method for training a Vision Transformer 78 machine learning model according to an embodiment of the invention comprises: providing training images of objects comprising integrated circuit patterns, the training images comprising annotated defects; partitioning each training image into patches; and training the Vision Transformer 78 machine learning model by iteratively presenting one or more training images to the Vision Transformer 78 machine learning model, wherein at least one patch of each training image is masked, and modifying the parameters of the vision transformer 78 machine learning model by minimizing a loss function configured for highlighting defects.

According to a preferred embodiment of the invention, the patches are defined using meta information from the group comprising critical dimension, relevant and/or irrelevant locations, structures or structure types, design information of the object comprising integrated circuit patterns. The critical dimension contains information on structure sizes and structure distances in the object comprising integrated circuit patterns that can, for example, be used to define minimum or maximum patch sizes. Information on relevant and/or irrelevant locations, structures or structure types can, for example, be used to leave out irrelevant locations or structures during masking or to adapt the weight of the loss function according to the relevance of the locations, structures or structure types. Design information of the object comprising integrated circuit patterns comprises locations of the integrated circuit patterns, e.g., in the form of polygons. Knowledge on the location relative to the polygon structures, a polygon density, a polygon size, a location within the integrated circuit pattern, etc., can be used to improve the training process. For example, the patches can be defined to include complete structures or parts of structures in order to prevent a defect from lying in two or more patches. Knowledge on typical defect locations can also be used to define patches such that the typical defect lies within a single or a small number of patches. In another example, programmed artificial defects can be added to the polygon structures of the design, and patches can be specifically defined to contain these artificial defects or parts thereof. In this way, the division of defects by patch boundaries is prevented or at least reduced.

According to an example, the machine learning model for defect highlighting 43 computes a reconstruction of the imaging dataset 22, and the loss function comprises a deviation of the reconstruction from the imaging dataset 22. In this way, the machine learning model for defect highlighting 43 learns to reconstruct the imaging dataset 22 with high accuracy. Parts of the imaging dataset that are not reconstructed can indicate defects, since defects correspond to rare structures in the imaging dataset 22.

In a preferred embodiment, the loss function applies a higher penalty, e.g., a higher weight, to deviations of the reconstruction from the imaging dataset 22 within defective regions 53 than within defect-free regions 54. In this way, contrary to standard autoencoders, most information of the defects 24 is preserved in the reconstruction. Thus, a comparison of the reconstruction to a reference dataset 42 can be used to detect defects 24, since the defects are highlighted in the reconstruction.

According to an aspect of the invention, the loss function is configured to highlight features within the defects 24. Features to be highlighted can include boundaries of the defect, center points, edges, structures, etc. In addition or alternatively, the loss function can be configured to modify properties of the imaging dataset 22 within defective regions 53. Properties of the imaging dataset 22 include, for example, brightness, contrast, intensity, color, focus, sharpness, distortions, noise, etc.

According to a preferred example, the majority of defects 24 in the training images are weakly annotated. Weakly annotated means that the annotation of the defect comprises pixels that do not belong to the defect and/or that the annotation does not contain all pixels that belong to the defect. For example, weak annotations comprise bounding boxes of any size and shape, circumcircles, center points, boundary points, one or more coordinates of the defect, partial annotations (comprising only a subset of the pixels of the defects), etc. Such weak annotations define defective regions 53 that can be used as training data in the machine learning model. By using weak annotations, the user effort can be immensely reduced, since the user is not required to indicate a pixel-wise segmentation of the defects 24 in the training images.

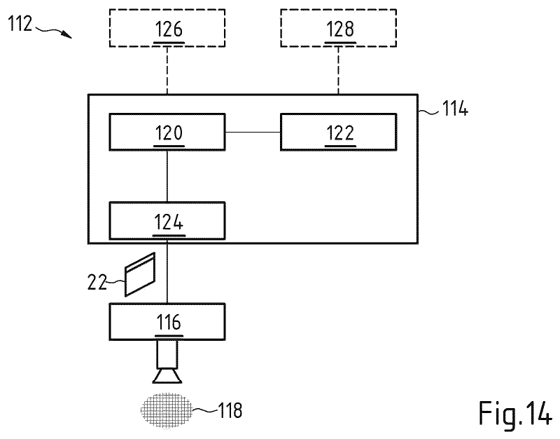

A system 112 for defect detection according to an embodiment of the invention illustrated in FIG. 14 comprises an imaging device 116 configured to provide an imaging dataset 22 of an object 118 comprising integrated circuit patterns and a data analysis device 114 comprising one or more processing devices 120 and one or more machine-readable hardware storage devices 122 comprising instructions that are executable by one or more processing devices 120 to apply a method for defect detection according to a computer implemented method 26 for defect detection as described above.

The system 112 optionally comprises a database 126 for loading and/or saving data, e.g., machine learning models, pre-trained machine learning models, training data, hyperparameters, training parameters, reference datasets, defect properties, computation time etc. The imaging device 116 for obtaining an imaging dataset 22 of the object 118 comprising integrated circuit patterns can comprise a charged particle beam device, for example, a Helium ion microscope, a cross-beam device including FIB and SEM, an atomic force microscope or any charged particle imaging device, or an aerial image acquisition system. The imaging device 116 for obtaining an imaging dataset 22 of the object 118 comprising integrated circuit patterns can provide an imaging dataset 22 to the data analysis device 114. The data analysis device 114 includes one or more processors 120, e.g., implemented as a central processing unit (CPU), graphics processing unit (GPU) or tensor processing unit (TPU). The one or more processors 120 can receive the imaging dataset 22 via an interface 124. The one or more processors 120 can load program code from a hardware-storage device 122, e.g., program code for executing a computer implemented method 26 for defect detection according to an embodiment of the invention as described above, or for training a machine learning model as described above, etc. The one or more processors 120 can execute the program code. Each data processor can include one or more processor cores, and each processor core can include logic circuitry for processing data. For example, a data processor can include an arithmetic and logic unit (ALU), a control unit, and various registers. Each data processor can include cache memory. Each data processor can include a system-on-chip (SoC) that includes multiple processor cores, random access memory, graphics processing units, one or more controllers, and one or more communication modules. Each data processor can include millions, billions or more of transistors. The system 112 optionally comprises a user interface 128, e.g., for monitoring the training progress of a machine learning model, for selecting training parameters, etc.

In some implementations, after the defects in a photolithography mask (or another object such as a semiconductor wafer that includes integrated circuit patterns) are detected using the methods and systems described above, the photolithography mask can be modified to repair or eliminate the defects. Repairing the defects can include, e.g., depositing materials on the photolithography mask using a deposition process, or removing materials from the photolithography mask using an etching process. Some defects can be repaired based on exposure with focused electron beams and adsorption of precursor molecules.

In some implementations, a repair device for repairing the defects on a photolithography mask can be configured to perform an electron beam-induced etching and/or deposition on the photolithography mask. The repair device can include, e.g. an electron source, which emits an electron beam that can be used to perform electron beam-induced etching or deposition on the object. The repair device can include mechanisms for deflecting, focusing and/or adapting the electron beam. The repair device can be configured such that the electron beam is able to be incident on a defined point of incidence on the photolithography mask.

The repair device can include one or more containers for providing one or more deposition gases, which can be guided to the photolithography mask via one or more appropriate gas lines. The repair device can also include one or more containers for providing one or more etching gases, which can be provided on the photolithography mask via one or more appropriate gas lines. Further, the repair device can include one or more containers for providing one or more additive gases that can be supplied to be added to the one or more deposition gases and/or the one or more etching gases.

The repair device can include a user interface to allow an operator to, e.g., operate the repair device and/or read out data.

The repair device can include a computer unit configured to cause the repair device to perform one or more of the methods described herein, based at least in part on an execution of an appropriate computer program.

In some implementations, the information about the defects serve as feedback to improve the process parameters of the manufacturing process for producing the photolithography masks. The process parameters can include, e.g., exposure time, focus, illumination, etc., For example, after the defects are identified from a first photolithography mask or first batch of photolithography masks, the process parameters of the manufacturing process are adjusted to reduce defects in a second mask or a second batch of masks.

In some implementations, a method for processing defects includes detecting at least one defect in a photolithography mask using the method for defect detection described above; and modifying the photolithography mask to at least one of reduce, repair, or remove the at least one defect.

For example, modifying the photolithography mask can include at least one of (i) depositing one or more materials onto the photolithography mask, (ii) removing one or more materials from the photolithography mask, or (iii) locally modifying a property of the photolithography mask.

For example, locally modifying a property of the photolithography mask can include writing one or more pixels on the photolithography mask to locally modify at least one of a density, a refractive index, a transparency, or a reflectivity of the photolithography mask.

In some implementations, a method of processing defects includes: processing a first photolithography mask using a manufacturing process that comprises at least one process parameter; detecting at least one defect in the first photolithography mask using the method for defect detection described above; and modifying the manufacturing process based on information about the at least one defect in the first photolithography mask that has been detected to reduce the number of defects or eliminate defects in a second photolithography mask to be produced by the manufacturing process.

For example, modifying the manufacturing process can include modifying at least one of an exposure time, focus, or illumination of the manufacturing process.

In some implementations, a method for processing defects includes: processing a plurality of regions on a first photolithography mask using a manufacturing process that comprises at least one process parameter, wherein different regions are processed using different process parameter values; applying the method for defect detection described above to each of the regions to obtain information about zero or more defects in the region; identifying, using a quality criterion or criteria, a first region among the regions based on information about the zero or more defects; identifying a first set of process parameter values that was used to process the first region; and applying the manufacturing process with the first set of process parameter values to process a second photolithography mask.

The methods disclosed herein can, for example, be used during research and development of objects comprising integrated circuit patterns or during high volume manufacturing of objects comprising integrated circuit patterns, or for process window qualification or enhancement. In addition, the methods disclosed herein can also be used for defect detection of X-ray imaging datasets of objects comprising integrated circuit patterns, e.g., after packaging the semiconductor device for delivery.

Reference throughout this specification to “an embodiment” or “an example” or “an aspect” means that a particular feature, structure or characteristic described in connection with the embodiment, example or aspect is included in at least one embodiment, example or aspect. Thus, appearances of the phrases “according to an embodiment,” “according to an example” or “according to an aspect” in various places throughout this specification are not necessarily all referring to the same embodiment, example or aspect, but may refer to different embodiments, examples, or aspects.

Furthermore, the particular features or characteristics may be combined in any suitable manner, as would be apparent to one of ordinary skill in the art from this disclosure, in one or more embodiments.

Furthermore, while some embodiments, examples or aspects described herein include some but not other features included in other embodiments, examples or aspects combinations of features of different embodiments, examples or aspects are meant to be within the scope of the claims, and form different embodiments, as would be understood by those skilled in the art.

Although the present invention is defined in the attached claims, it should be understood that the present invention can also be defined in accordance with the following embodiments:

Embodiment 1: A computer implemented method (26) for defect detection comprising:
obtaining an imaging dataset (22) and a reference dataset (42) of an object (118) comprising integrated circuit patterns; and
detecting defects (24) in the imaging dataset (22) using the imaging dataset (22) and the reference dataset (42), wherein a machine learning model for defect highlighting (43) is applied to the imaging dataset (22) as input and generates a highlighted defect dataset (44) as output, and wherein the machine learning model for defect highlighting (43) comprises at least one attention mechanism (27).

Embodiment 2: The method of embodiment 1, wherein the reference dataset (42) is generated using a further machine learning model (48).

Embodiment 3: The method of embodiment 2, wherein the further machine learning model (48) comprises at least one attention mechanism (27).

Embodiment 4: The method of any one of embodiments 1 to 3, wherein defects (24) are detected by comparing the highlighted defect dataset (44) to the reference dataset (42).

Embodiment 5: The method of any one of embodiments 1 to 3, wherein the machine learning model for defect highlighting (43) uses the reference dataset (44) as additional input.

Embodiment 6: The method of embodiment 5, wherein the machine learning model for defect highlighting (43) maps the imaging dataset (22) and the reference dataset (42) to the highlighted defect dataset (44).

Embodiment 7: The method of embodiment 5, wherein the machine learning model for defect highlighting (43) reconstructs the imaging dataset (22) and the reference dataset (42), and wherein the highlighted defect dataset (44) is obtained by comparing the reconstruction of the imaging dataset (50) to the reconstruction of the reference dataset (52).

Embodiment 8: The method of any one of embodiments 1 to 7, wherein the machine learning model for defect highlighting (43) computes a reconstruction of the input including the defects (24).

Embodiment 9: The method of embodiment 8, wherein the machine learning model for defect highlighting (43) reconstructs defective regions (53) in the input with a higher accuracy than defect-free regions (54).

Embodiment 10: The method of embodiment 8 or 9, wherein the machine learning model for defect highlighting (43) amplifies the defects (24) in the input.

Embodiment 11: The method of any one of embodiments 1 to 10, wherein the machine learning model for defect highlighting (43) comprises a convolutional neural network that contains at least one attention mechanism (27).

Embodiment 12: The method of embodiment 11, wherein the convolution neural network comprises an encoder—decoder architecture.

Embodiment 13: The method of embodiment 11 or 12, wherein the convolutional neural network is configured as a U-Net (65).

Embodiment 14: The method of any one of embodiments 1 to 10, wherein the machine learning model for defect highlighting (43) comprises a Vision Transformer (78).

Embodiment 15: The method of embodiment 14, wherein the Vision Transformer (78) is pre-trained using masked autoencoding.

Embodiment 16: The method of embodiment 14 or 15, wherein the detection of defects (24) comprises:
partitioning the imaging dataset (22) of the object (118) comprising integrated circuit patterns into a set of patches (80);
iteratively masking one or more of the patches (80) of the imaging dataset (22) and applying the Vision Transformer (78) machine learning model to reconstruct the one or more masked patches (98); and
obtaining a highlighted defect dataset (44) in the form of a reconstructed imaging dataset from the one or more reconstructed masked patches.

Embodiment 17: The method of any one of embodiments 1 to 16, wherein the input to the machine learning model additionally comprises one or more meta tokens (90) representing meta information concerning the imaging dataset (22) and/or the imaging device (116) used to obtain the imaging dataset (22).

Embodiment 18: A computer implemented method for training a machine learning model for defect highlighting (43) according to any one of embodiments 1 to 17, the method comprising:
providing training images of objects (118) comprising integrated circuit patterns; and
training the machine learning model for defect highlighting (43) using the provided training images by minimizing a loss function configured for highlighting defects (24).

Embodiment 19: A computer implemented method for training a Vision Transformer (78) machine learning model according to any one of embodiments 14 to 17, the method comprising:
providing training images of objects (118) comprising integrated circuit patterns;
partitioning each training image into patches (80); and
training the Vision Transformer (78) machine learning model by iteratively presenting one or more training images to the Vision Transformer (78) machine learning model, wherein one or more patches (80) of each training image are masked, and modifying the parameters of the Vision Transformer (78) machine learning model by minimizing a loss function configured for highlighting defects (24).

Embodiment 20: The method of embodiment 19, wherein the patches (80) are defined using meta information from the group comprising critical dimension, relevant and/or irrelevant locations, structures or structure types, design information of the object (118) comprising integrated circuit patterns.

Embodiment 21: The method of any one of embodiments 18 to 20, wherein the machine learning model for defect highlighting (43) computes a reconstruction of the imaging dataset (22), and wherein the loss function comprises a deviation of the reconstruction from the imaging dataset (22).

Embodiment 22: The method of any one of embodiments 18 to 21, wherein the training images comprise annotated defects.

Embodiment 23: The method of embodiment 21, wherein the training images comprise annotated defects, and the loss function applies a higher penalty to deviations of the reconstruction from the imaging dataset (22) within defective regions (53) than within defect-free regions (54).

Embodiment 24: The method of embodiment 22 or 23, wherein the loss function is configured to highlight features within the defects (24).

Embodiment 25: The method of any one of embodiments 22 to 24, wherein the loss function is configured to modify properties of the imaging dataset (22) within defective regions (53).

Embodiment 26: The method of any one of embodiments 22 to 25, wherein the majority of defects (24) in the training images are weakly annotated.

Embodiment 27: A computer program comprising instructions which, when the program is executed by a computer, cause the computer to carry out a method for defect detection (26) of any one of embodiments 1 to 26.

Embodiment 28: A computer-readable medium, on which a computer program executable by a computing device is stored, the computer program comprising code for executing a method for defect detection (26) of any one of embodiments 1 to 26.

Embodiment 29: A system (112) for defect detection comprises:
an imaging device (116) configured to provide an imaging dataset (22) of an object (118) comprising integrated circuit patterns;
one or more processing devices (120); and
one or more machine-readable hardware storage devices (122) comprising instructions that are executable by one or more processing devices (120) to apply a method for defect detection (26) according to any one of embodiments 1 to 26 to the imaging dataset (22) of the object (118) comprising integrated circuit patterns.

In summary, in a general aspect, the invention relates to a computer implemented method 26 for defect detection comprising: obtaining an imaging dataset 22 and a reference dataset 42 of an object 118 comprising integrated circuit patterns; and detecting defects 24 in the imaging dataset 22 using the imaging dataset 22 and the reference dataset 42, wherein a machine learning model for defect highlighting 43 is applied to the imaging dataset 22 as input and generates a highlighted defect dataset 44 as output, and wherein the machine learning model for defect highlighting 43 comprises at least one attention mechanism 27. The invention also relates to computer programs, computer-readable media and corresponding systems.

### REFERENCE NUMBER LIST

10, 10′ Photolithography system
12 Light source
14 Photolithography mask
16 Illumination optics
18 Projection optics
20 Wafer
22 Imaging dataset
24 Defect
26 Computer implemented method
27 Attention mechanism
28 Token
28′ Feature vector
29 Multilayer perceptron
30 Query
31 Key
32 Value
33 Similarity function
33′ Attention distribution
34 Attention weighted values
35 Aggregation function
36 Attention-based representation
37 Transformer block
38 Multihead attention
39 Add & norm layer
40 Feed forward neural network
41 Positional encoding
42 Reference dataset
43 Machine learning model for defect highlighting
44 Defect dataset
46, 46′ Highlighted defect
48 Further machine learning model
50 Reconstruction of the imaging dataset
52 Reconstruction of the reference dataset
53 Defective region
54 Defect-free region
56 Absent structure
58 Regularized reference dataset
60 Region with irregular structures
62 Convolution feature maps
65 U-Net
66 Conv 3×3 batch norm operation
68 Max pool 2×2 operation
70 Up-conv 2×2 operation
72 Copy and concatenate operation
74 Input data
76 Output data
78 Vision Transformer
80 Patch
82 Linear projection of flattened patches
84 Positional encoding
86 Transformer-encoder
88 MLP Head
90 Meta token
92 Patch and position embedding
98 Masked patches
100 Decoder
102 Unmasked patches
104 Encoded patches
106 Combined patches
108 Decoded patches
112 System
114 Data analysis device
116 Imaging device
118 Object
120 Processing device
122 Hardware-storage device
124 Interface
126 Database
128 User interface

What is claimed is:

1. A computer implemented method for defect detection comprising:
obtaining an imaging dataset and a reference dataset of an object comprising integrated circuit patterns,
detecting defects in the imaging dataset using the imaging dataset and the reference dataset, wherein a machine learning model for defect highlighting is applied to the imaging dataset as input and generates a highlighted defect dataset as output, and wherein the machine learning model for defect highlighting comprises at least one attention mechanism.

2. The method of claim 1, wherein the reference dataset is generated using a further machine learning model.

3. The method of claim 2, wherein the further machine learning model comprises at least one attention mechanism.

4. The method of claim 1, wherein defects are detected by comparing the highlighted defect dataset to the reference dataset.

5. The method of claim 1, wherein the machine learning model for defect highlighting uses the reference dataset as additional input.

6. The method of claim 5, wherein the machine learning model for defect highlighting maps the imaging dataset and the reference dataset to the highlighted defect dataset.

7. The method of claim 5, wherein the machine learning model for defect highlighting reconstructs the imaging dataset and the reference dataset, and wherein the highlighted defect dataset is obtained by comparing the reconstruction of the imaging dataset to the reconstruction of the reference dataset.

8. The method of claim 1, wherein the machine learning model for defect highlighting computes a reconstruction of the input including the defects.

9. The method of claim 8, wherein the machine learning model for defect highlighting reconstructs defective regions in the input with a higher accuracy than defect-free regions.

10. The method of claim 8, wherein the machine learning model for defect highlighting amplifies the defects in the input.

11. The method of claim 1, wherein the machine learning model for defect highlighting comprises a convolutional neural network that contains at least one attention mechanism.

12. The method of claim 11, wherein the convolution neural network comprises an encoder—decoder architecture.

13. The method of claim 11, wherein the convolutional neural network is configured as a U-Net.

14. The method of claim 1, wherein the machine learning model for defect highlighting comprises a Vision Transformer.

15. The method of claim 14, wherein the Vision Transformer is pre-trained using masked autoencoding.

16. The method of claim 14, wherein the detection of defects comprises:
partitioning the imaging dataset of the object comprising integrated circuit patterns into a set of patches;
iteratively masking one or more of the patches of the imaging dataset and applying the Vision Transformer machine learning model to reconstruct the one or more masked patches; and
obtaining a highlighted defect dataset in the form of a reconstructed imaging dataset from the one or more reconstructed masked patches.

17. The method of claim 1, wherein the input to the machine learning model additionally comprises one or more meta tokens representing meta information concerning the imaging dataset and/or the imaging device used to obtain the imaging dataset.

18. A computer implemented method for training a machine learning model for defect highlighting according to claim 1, the method comprising:
providing training images of objects comprising integrated circuit patterns; and
training the machine learning model for defect highlighting using the provided training images by minimizing a loss function configured for highlighting defects.

19. A computer implemented method for training a Vision Transformer machine learning model according to claim 14, the method comprising:
providing training images of objects comprising integrated circuit patterns;
partitioning each training image into patches; and
training the Vision Transformer machine learning model by iteratively presenting one or more training images to the Vision Transformer machine learning model, wherein one or more patches of each training image are masked, and modifying the parameters of the Vision Transformer machine learning model by minimizing a loss function configured for highlighting defects.

20. The method of claim 19, wherein the patches are defined using meta information from the group comprising critical dimension, relevant and/or irrelevant locations, structures or structure types, design information of the object comprising integrated circuit patterns.

21. The method of claim 19, wherein the machine learning model for defect highlighting computes a reconstruction of the imaging dataset, and wherein the loss function comprises a deviation of the reconstruction from the imaging dataset.

22. The method of claim 19, wherein the training images comprise annotated defects.

23. The method of claim 21, wherein the training images comprise annotated defects, and the loss function applies a higher penalty to deviations of the reconstruction from the imaging dataset within defective regions than within defect-free regions.

24. The method of claim 22, wherein the loss function is configured to highlight features within the defects.

25. The method of claim 22, wherein the loss function is configured to modify properties of the imaging dataset within defective regions.

26. The method of claim 22, wherein the majority of defects in the training images are weakly annotated.

27. A computer program comprising instructions which, when the program is executed by a computer, cause the computer to carry out a method for defect detection of claim 1.

28. A computer-readable medium, on which a computer program executable by a computing device is stored, the computer program comprising code for executing a method for defect detection of claim 1.

29. A system for defect detection comprises:
an imaging device configured to provide an imaging dataset of an object comprising integrated circuit patterns;
one or more processing devices; and
one or more machine-readable hardware storage devices comprising instructions that are executable by one or more processing devices to apply a method for defect detection according to claim 1 to the imaging dataset of the object comprising integrated circuit patterns.
